(19) United States
(12) Patent Application Publication
(10) Pub. No.: US 2007/0164448 A1
(43) Pub. Date: Jul. 19, 2007

(54) Semiconductor chip package with attached electronic devices, and integrated circuit module having the same

(75) Inventors: Kyoung-Sun Kim, Uijeongbu-si (KR); Ki-Hyun Ko, Yongin-si (KR); Byoung-Ha Oh, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/505,361

(22) Filed: Aug. 17, 2006

(30) Foreign Application Priority Data
Jan. 18, 2006 (KR) 2006-0005275

(51) Int. Cl. H01L 23/48

(52) U.S. Cl. 257/778

(57) ABSTRACT

Provided are a semiconductor chip package with attached electronic devices, and an integrated circuit module having the same. The semiconductor chip packages may include a supporting substrate, input/output bonding pads arranged on a first plane of the supporting substrate, and device bonding pads arranged on the edges of the first plane or portions of the first plane adjacent to the edges. Accordingly, the mount area of a printed circuit board may be reduced, efficient routing may be possible, and the occurrence of package cracks may be reduced and/or prevented.

### PRIORITY STATEMENT

This application claims the benefit of priority to Korean Patent Application No. 10-2006-0005275, filed Jan. 18, 2006, the entire contents of which is hereby incorporated by reference.

### BACKGROUND OF THE INVENTION

1. Technical Field

Example embodiments of the present invention relate to a semiconductor chip package with attached electronic devices, and an integrated circuit module including the same. More particularly, example embodiments of the present invention are directed to a semiconductor chip package with attached electronic devices that reduces and/or prevents the occurrence of semiconductor chip package cracks and reduces the mount area and an integrated circuit module having the same.

2. Discussion of Related Art

Electronic products have been developed that may have characteristics including small size, light weight and high performance. Conventionally, the tendency of semiconductor chip packages used in the electronic products is directed towards providing high performance products. This tendency may not adequately consider the detrimental effects of the noise characteristics of semiconductor chip packages and may result in deteriorated performance of the semiconductor chip packages due to noise.

To reduce and/or eliminate the influence of noise and to clarify input/output signals in semiconductor chip packages, decoupling devices, for example, capacitors, resistors, etc., which may have pre-calculated values, have been used as circuits in integrated circuit modules including the semiconductor chip packages.

A ball grid array (BGA) package is one type of semiconductor chip package used for high performance. Accordingly, the BGA package is commonly used in manufacturing electronic products. As the integration density of semiconductor devices increases, the number of required input/output pins generally increases and more efficient heat emission is generally preferred and/or required. The BGA package has been developed at least in part due to these factors. The structure of the BGA package is accommodating to a semiconductor chip package having a lot of pins because external connection terminals are generally arranged in a planar array. Further, the BGA package is useful because the mount area used for mounting the package is generally reduced. Still further, the BGA package is generally used because the BGA package may provide excellent heat resistance and electric characteristics.

FIG. 1 is a schematic view illustrating a conventional BGA package and an integrated circuit module 50 including the conventional BGA package.

As illustrated in FIG. 1, the conventional integrated circuit module 50 may include a BGA package 20 including solder balls 30; electronic devices 40, which may be used as decoupling devices; and a printed circuit board 10.

The BGA package 20 may have a structure in which a semiconductor die (not shown) may be mounted on a supporting substrate. The semiconductor die may refer to a semiconductor device, for example, a silicon memory device which is not protected or packaged by plastic, epoxy or other materials.

The electronic devices 40 may refer to capacitors and/or resistors, and/or may include a plurality of capacitors and/or resistors. The electronic devices 40 may be positioned on the printed circuit board 10, and may be electrically connected with input/output pads of the semiconductor die by pattern routing on the printed circuit board 10.

The printed circuit board 10 may include a space for mounting one or more semiconductor chip packages, and for at least this purpose, may include circuit pattern routing. In addition, the printed circuit board 10 may include a space for attaching the electronic devices, and for at least this purpose, may include circuit pattern routing. The printed circuit board 10 may also include circuit pattern routing to interface with one or more additional printed circuit boards.

For at least the above-described reasons, the conventional integrated circuit module 50 may have a structure that the decoupling devices 40 and the BGA package 20 are mounted to the printed circuit board 10. Thus, the printed circuit board 10 of the conventional integrated circuit module 50 generally requires additional space for the electronic devices 40 such as decoupling devices, for example, in addition to the space provided for the BGA package 20. Further, the conventional integrated circuit module 50 may require additional circuit pattern routing for electrically connecting the electronic devices 40 and the semiconductor die.

In conventional devices, edges of the BGA package 20 may be weak and very susceptible to external impacts. That is, the edges or portions 22 adjacent to the edges, where the solder balls 30 are not attached, may be weak and susceptible to external impacts because there are no supporting elements, for example, solder balls 30 in these portions. As illustrated in FIG. 1, package cracks may occur causing the fragile portions 22 to break and solder joint cracks may occur causing the solder balls 30 arranged on the edges or portions adjacent to the edges to separate from the package 20 and/or break.

FIG. 2 illustrates a conventional integrated circuit module 60 developed at least in part to mitigate and/or solve the problems of the conventional integrated circuit module 50 described with respect to FIG. 1.

As illustrated in FIG. 2, the conventional integrated circuit module 60 may include dummy balls 50 on the printed circuit board 10 arranged between the edges of the package 20 and the printed circuit board 10 to mitigate and/or solve the problems of the package cracks and/or solder joint cracks. However, in the structure of the integrated circuit module 60 shown in FIG. 2, pattern routing conventionally cannot be performed around the dummy balls 50 positioned on the printed circuit board 10. Moreover, in the conventional integrated circuit module 60, it is still necessary to provide space for the electronic devices 40 on the printed circuit board 10 and to provide additional circuit pattern routing for electrically connecting the electronic devices 40 with the semiconductor die.

### SUMMARY OF THE INVENTION

Example embodiments of the present invention are directed towards providing a semiconductor chip package with attached electronic devices, and an integrated circuit module having the same.

Example embodiments of the present invention are directed towards providing a semiconductor chip package with attached electronic devices, and an integrated circuit module having the same to reduce and/or prevent the occurrence of package cracks and/or solder joint cracks.

Example embodiments of the present invention are directed towards providing a semiconductor chip package with attached electronic devices, and an integrated circuit module having the same, to reduce the mount area and to reduce and/or eliminate additional pattern routing used for the electronic devices.

An example embodiment of the present invention provides a semiconductor chip package. The semiconductor chip package may include a supporting substrate, a plurality of input/output bonding pads arranged on a first plane of the supporting substrate, and a plurality of device bonding pads arranged on at least one of edges of the first plane and portions of the first plane adjacent to the edges.

An example embodiment of the present invention provides a semiconductor chip package. The semiconductor chip package may include a supporting substrate, a plurality of input/output bonding pads arranged on a first plane of the supporting substrate, a semiconductor die including input/output pads, and a plurality of protrusions having a length and being arranged on at least one of edges of the first plane and portions adjacent to the edges. The input/output pads of the semiconductor die are connected to the input/output bonding pads arranged on the first plane of the substrate.

An example embodiment of the present invention provides a semiconductor chip package. The semiconductor chip package may include a semiconductor die; a supporting substrate where the semiconductor die is mounted; a plurality of input/output bonding pads arranged on one plane of the supporting substrate and electrically connected with input/output pads of the semiconductor die; and a plurality of device bonding pads positioned at edges and/or portions adjacent to the edges on the one plane of the supporting substrate.

According to an example embodiment of the present invention, the semiconductor chip package may have a ball grid array (BGA) package structure, and the input/output bonding pads on the one plane of the supporting substrate may comprise a plurality of solder balls having the same size and the same ball pitch and attached to the input/output bonding pads.

According to an example embodiment of the present invention, the device bonding pads may be attached to electronic devices including active and/or passive devices, and the electronic devices may be smaller than or same as the solder balls in size. The electronic devices may be decoupling devices including capacitors and/or resistors.

An example embodiment of the present invention provides a semiconductor chip package. The semiconductor chip package may include device bonding pads for at least two or more electronic devices at edges and portions adjacent to the edges of the one plane of the semiconductor chip package including input/output bonding pads.

According to an example embodiment of the present invention, the electronic devices may be decoupling devices including capacitors and/or resistors.

An example embodiment of the present invention provides an integrated circuit module. The integrated circuit module may include a semiconductor chip package including a semiconductor die, a plurality of input/output bonding pads arranged on one plane of the semiconductor die and electrically connected with input/output pads of the semiconductor die, and a plurality of device bonding pads positioned at edges and/or portions adjacent to the edges of the one plane of the semiconductor die; a plurality of solder balls having the same size and the same ball pitch and attached to the input/output bonding pads of the semiconductor chip package; a plurality of electronic devices electrically connected with the device bonding pads; and a printed circuit board electrically connected with the semiconductor chip package through the solder balls but not electrically connected with the electronic devices, and having circuit pattern routing for mounting at least one or more semiconductor chip packages.

According to an example embodiment of the present invention, the semiconductor chip package may have a ball grid array (BGA) package structure, and the electronic devices may include active and/or passive devices. The electronic devices may be smaller than or same as the solder balls in size, and the electronic devices may be decoupling devices including capacitors and/or resistors.

According to an example embodiment of the present invention, if the electronic devices are bigger than the solder balls in size, an interposer for providing an electrical connection may be included between the semiconductor chip package and the printed circuit board.

An example embodiment of the present invention provides a semiconductor chip package. The semiconductor chip package may include a semiconductor die, and input/output bonding pads electrically connected with input/output pads of the semiconductor die and arranged on the one plane of the semiconductor die, comprising a plurality of protrusions having a regular length and positioned at edges or portions adjacent to the edges at the one plane of the semiconductor die, spaced apart from one another at regular intervals.

According to an example embodiment of the present invention, the semiconductor chip package may have a ball grid array (BGA) structure and further comprise a plurality of solder balls having the same size and the same ball pitch and attached to the input/output bonding pads. The protrusions may be smaller than or same as the solder balls in size. Further, the protrusions may comprise decoupling capacitors and/or resistors electrically connected with the semiconductor die.

According to example embodiments of the present invention, a mount area may be reduced, efficient routing may be possible, and the occurrence of package cracks and/or solder cracks may be reduced and/or prevented.

### BRIEF DESCRIPTION OF THE DRAWINGS

The above and other features and/or advantages of the present invention will become more apparent to those of ordinary skill in the art by describing in detail example embodiments of the present invention with reference to the attached drawings in which:

FIG. 1 is a schematic view illustrating an example of a conventional semiconductor chip package and an integrated circuit module having the same;

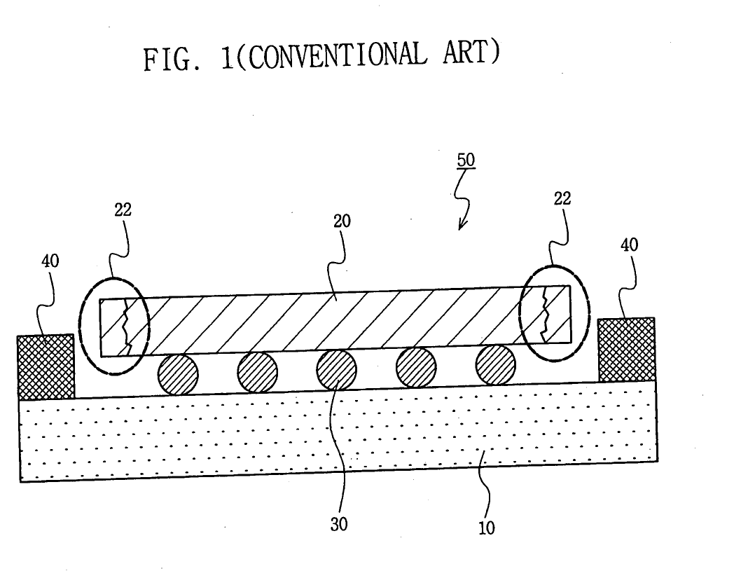

FIG. 2 is a schematic view illustrating an example of a conventional semiconductor chip package and an integrated circuit module having the same;

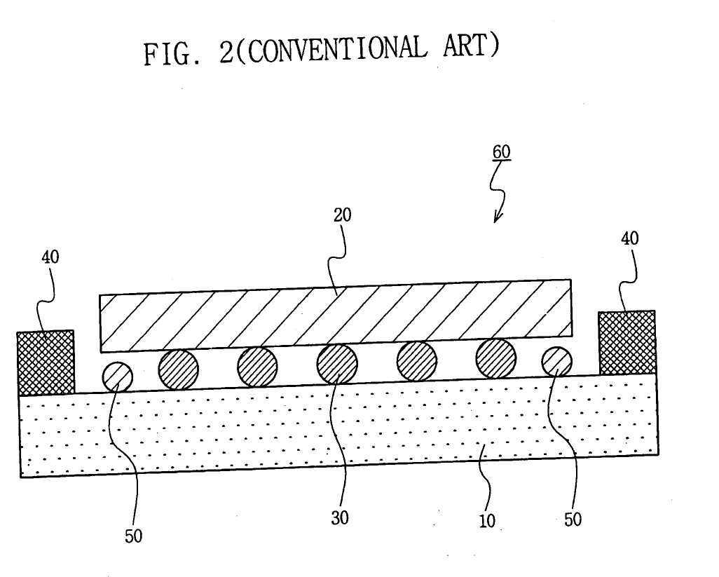

FIG. 3 is a schematic view illustrating a semiconductor chip package and an integrated circuit module having the same according to an example embodiment of the present invention;

FIG. 4 is a view illustrating a plane of the semiconductor chip package of FIG. 3;

FIG. 5 is a schematic view of a semiconductor chip package and an integrated circuit module having the same according to an example embodiment of the present invention; and

FIG. 6 is a schematic view of a semiconductor chip package and an integrated circuit module having the same according to an example embodiment of the present invention.

### DETAILED DESCRIPTION OF EXAMPLE EMBODIMENTS OF THE PRESENT INVENTION

Detailed illustrative embodiments of the present invention are disclosed herein. This invention may, however, be embodied in many alternate forms and should not be construed as limited to only the example embodiments of the present invention set forth herein.

Accordingly, while example embodiments of the present invention are capable of various modifications and alternative forms, embodiments of the present invention are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Example embodiments of the present invention will now be described more fully hereinafter with reference to the accompanying drawings. These embodiments are provided so that this disclosure will be thorough and complete, and will fully convey the scope of the invention to those skilled in the art.

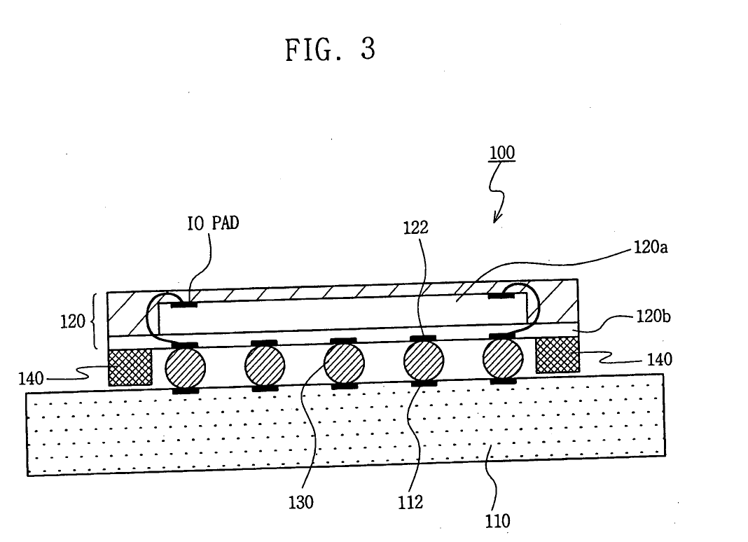

FIG. 3 schematically illustrates a semiconductor chip package and an integrated circuit module 100 having the same according to an example embodiment of the present invention.

As illustrated in FIG. 3, the integrated circuit module 100 may include a semiconductor chip package 120 including solder balls 130; electronic devices 140; and a printed circuit board 110.

The structure of the semiconductor chip package 120 according to an example embodiment of the present invention may vary. For example, quad flat package (QFP), plastic leaded chip carrier (PLCC), ceramic leaded chip carrier (CLCC), or ball grid array (BGA) structures may be used according to example embodiments of the present invention.

FIG. 3 illustrates a BGA package structure of an example embodiment of the present invention.

In the BGA package 120, a semiconductor die 120a may be mounted on a supporting substrate 120b. The semiconductor die 120a refers to a semiconductor device, for example, a silicon memory device, which may not be protected or packaged using plastic, epoxy, etc. A plurality of input/output bonding pads 122 may be arranged on a first plane of the supporting substrate 120b. The input/output bonding pads 122 may be electrically connected with input/output pads of the semiconductor die 120a. The supporting substrate 120b may include a circuit pattern or may be formed of a ceramic or epoxy material.

The BGA package 120 may include a wire electrically connecting the semiconductor die 120a and the supporting substrate 120b, and may be enclosed by a resin cover protecting the semiconductor die 120a and the wire from exterior corrosion and/or oxidation. The solder balls 130 electrically connected with the input/output bonding pads 122 may be attached to the input/output bonding pads 122 positioned under the supporting substrate 120b. The BGA package 120 may be mounted on the printed circuit board 110 using the solder balls 130, for example.

The BGA package 120 may have a chip on board (COB) structure where the semiconductor die 120a is mounted in the upper middle portion of the supporting substrate 120b, or a board on chip (BOC) structure where the semiconductor die 120a is mounted in the lower portion of the supporting substrate 120b.

An interior structure of the BGA package and/or a method of forming a BGA package is well known to artisans having ordinary knowledge in this art. Thus, any further description thereof is omitted for the sake of brevity.

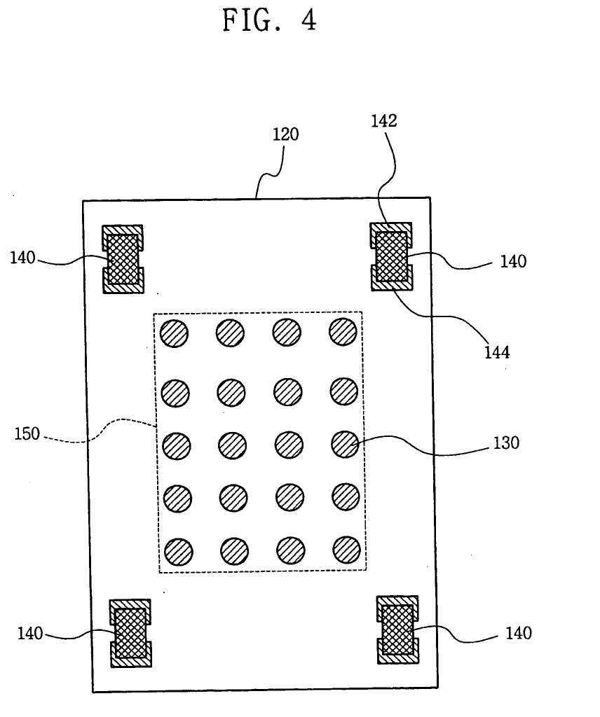

The BGA package 120 of FIG. 3 may also include device bonding pads 142 and 144 as shown in FIG. 4. The BGA package 120 including the device bonding pads 142 and 144 is different from the conventional BGA package. According to an example embodiment of the present invention, the device bonding pads 142 and 144 are not for the semiconductor die on the supporting substrate.

FIG. 4 illustrates the first plane of the BGA package 120. Here, the term ‘first plane’ means the side to which the solder balls 130 may be attached, for mounting on the printed circuit board 110. The BGA package 120 according to an example embodiment of the present invention should be understood as including the semiconductor die and the supporting substrate. The first plane of the supporting substrate may refer to a first plane of the BGA package 120.

As illustrated in FIG. 4, the device bonding pads 142 and 144 according to an example embodiment of the present invention may be used to attach the electronic devices 140, which may include decoupling devices. The decoupling devices should be understood by those skilled in the art to include one or more of a decoupling capacitor for improving the power characteristics of a semiconductor device, a capacitor for improving the characteristics of a reference voltage and smoothly supplying the reference voltage, and a stub resistor for improving signal characteristics, for example.

The device bonding pads 142 and 144 may be electrically connected with a power supply pad and/or ground pad of the semiconductor die by a wire or any other connecting units, and may have any other electrical connection structures if necessary and/or preferred.

The device bonding pads 142 and 144 may be formed in a first plane of the BGA package 120 where the input/output bonding pads 122 are formed. For example, the device bonding pads 142 and 144 may be formed at edges and portions adjacent to the edges of the first plane of the BGA package 120, and the edges and portions adjacent to the edges may be the space where the input/output bonding pads 122 for attaching the solder balls 130 are not positioned. For example, in FIG. 4 the edges and portions adjacent to the edges correspond to a region on the periphery of line 150. The line 150 is included in FIG. 4 for illustrative purposes.

Because the edges of a conventional package and the portions adjacent to the edges do not have any supporting units, it is possible to reduce and/or prevent the occurrence of package cracks and/or solder joint cracks according to example embodiments of the present invention because supporting units are formed at the edges of the BGA package 120 and/or the portions adjacent to the edges of the BGA package 120. Further, because decoupling devices 140 may be more efficient if the decoupling devices are positioned closer to the semiconductor die as shown in example embodiments of the present invention, it is possible to obtain advantageous effects as compared with conventional devices where the decoupling devices are positioned on the printed circuit board.

The electronic devices 140 attached to the device bonding pads 142 and 144 may be active devices and/or passive devices. Further, the same devices, for example, capacitors, may be attached to each of the device bonding pads 142 and 144. Alternatively, different devices may be attached to the device bonding pads 142 and 144. For example, one device pad may be connected to a resistor and another device pad may be connected to a capacitor. According to an example embodiment of the present invention, electronic devices 140 may not be bigger in size than the solder balls 130, but may be similar to the size to the solder balls 130 attached to the input/output bonding pads. Stated differently, if the height of each electronic device 140 is bigger than that of each solder ball 130, it may be difficult to mount the BGA package 120 on the printed circuit board 110. Further, if the height of each electronic device 140 is too much smaller than that of each solder ball 130, it may be difficult to achieve the objects of the present invention including for example, reducing and/or preventing the occurrence of package cracks and/or solder joint cracks.

The printed circuit board 110 may include circuit pattern routing to mount one or more semiconductor chip packages. As illustrated in FIG. 3, a number of solder lands 112 corresponding to the solder balls 130 may be formed at positions corresponding to where the BGA package 120 is to be mounted. Each solder land 112 may be formed in a shape corresponding to the shape of each solder ball 130. For example, the solder lands 112 may be round. The number of the solder lands 112 may be the same as the number of the input/output bonding pads 122 of the BGA package 120. However, no solder lands for the device bonding pads 142 and 144 are formed.

Thus, the printed circuit board 110 may be electrically connected with the BGA package 120 through the solder balls 130, but the printed circuit board 110 may not be electrically connected with the electronic devices 140.

In the integrated circuit module 100 of FIG. 3, signals output from the semiconductor die may be transferred to the input/output bonding pads 122 of the BGA package 120 through at least one wire. The signals transferred to the input/output bonding pads 122 may be transferred to the printed circuit board 110 through the solder balls 130 attached to the input/output bonding pads 122, and then, may be transferred to peripheral devices, except for the electronic devices 140 attached to the BGA package 120. If signals generated from the peripheral devices are transferred to the semiconductor die, the signals may be transferred in a reverse order of that described above. With respect to the electronic devices 140 attached to the BGA package 120, the signals output from the semiconductor die may be transferred to the device bonding pads 142 and 144 of the BGA package 120 through the at least one wire, and may be transferred to the electronic devices 140 through the device bonding pads 142 and 144. If the signals generated from the electronic devices 140 are transferred to the semiconductor die, the signals may be transferred in a reverse order.

In the integrated circuit module 100 according to the example embodiment of the present invention shown in FIG. 3, the printed circuit board 110 may reduce and/or eliminate the additional space for mounting the electronic devices 140 including the decoupling devices that is required in conventional devices. Further, the circuit pattern routing for the electronic devices 140 is not necessary on the printed circuit board 110 according to an example embodiment of the present invention. Because the circuit pattern routing may be possible at the printed circuit board 110 in contact with the electronic devices 140, more efficient circuit pattern routing may be possible as compared with conventional devices.

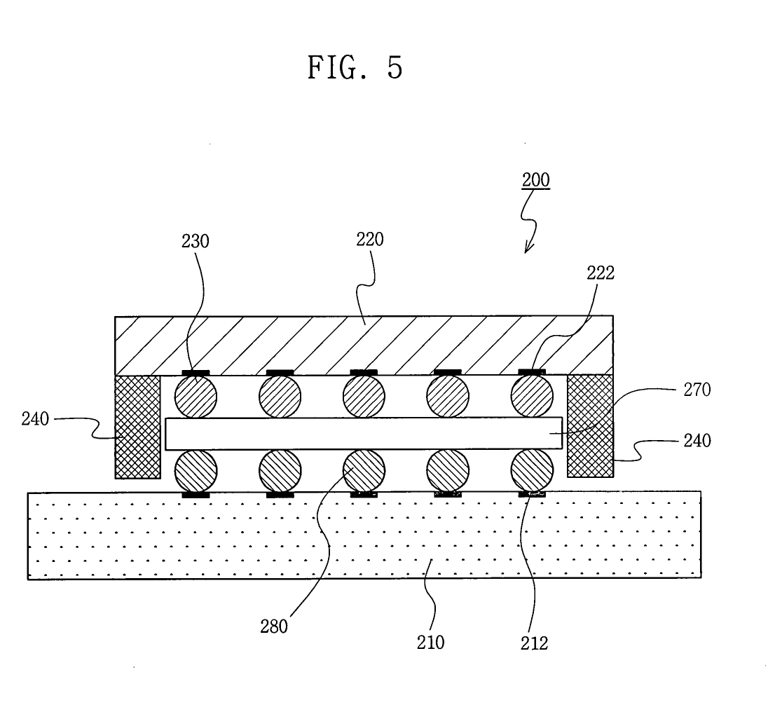

FIG. 5 schematically illustrates a semiconductor chip package 220 and an integrated circuit module 200 having the same according to an example embodiment of the present invention. In the semiconductor chip package 220 and the integrated circuit module 200 having the same, electronic devices 240 attached to the BGA package 220 may be bigger in size than solder balls 230.

The integrated circuit module 200 of FIG. 5 may include the semiconductor chip package 220 with solder balls 230 attached thereto; electronic devices 240 and a printed circuit board 210. The semiconductor chip package 220 and the printed circuit board 210 may be substantially similar to those of FIG. 3.

The electronic devices 240 may vary in size. Thus, if the electronic devices 240 are bigger in size than the solder balls 230, it may be difficult and/or impossible to attach the electronic devices 240 to the BGA package 220, using the structure shown in FIG. 3. A solution according to an example embodiment of the present invention, is to form bigger solder balls 230 or smaller electronic devices 240. However, if this solution is unavailable or undesirable because of increased cost, for example, an interposer 270 may be used according to an example embodiment of the present invention.

The interposer 270 may provide the flexibility of an electrical connection between the BGA package 220 and the printed circuit board 210. The interposer 270 may be made of an elastic material, for example, tape, or a polyimide or plastic material, for example. The interposer 270 may include a single patterned interconnection layer, a number of patterned interconnection layers, passive devices, etc.

The interposer 270 may be positioned between first solder balls 230, which may be attached to input/output bonding pads 222 on a first plane of the BGA package 220, and second solder balls 280, which may be attached to solder lands 212 of the printed circuit board 210. The interposer 270 may electrically connect each first solder ball 230 with a second solder ball 280.

The interposer 270 may be controlled with respect to its size (for example, thickness) so that the electronic devices 240 attached to the BGA package 220 may be positioned between the printed circuit board 210 and the BGA package 220.

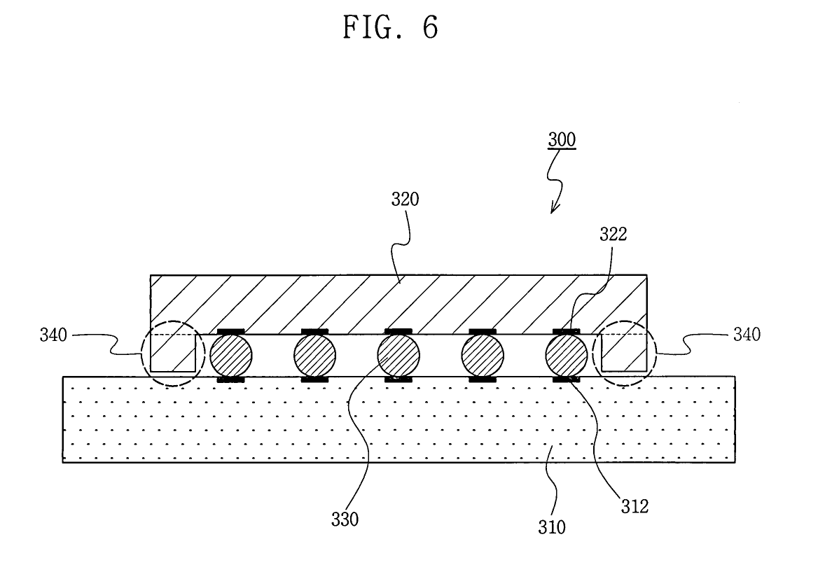

FIG. 6 schematically illustrates a semiconductor chip package 320 and an integrated circuit module 300 having the same according to an example embodiment of the present invention. In the example embodiment of the present invention shown in FIG. 6, the BGA package 320 may include electronic devices.

As illustrated in FIG. 6, the integrated circuit module 300 may include the semiconductor chip package 320 with solder balls 330 attached thereto and a printed circuit board 310. The solder balls 330 and the printed circuit board 310 may be substantially similar or the same as those of FIG. 3. The solder balls 330 may be attached to solder lands 312 of the printed circuit board 310 and to input/output bonding pads 322 of the BGA package 320.

The BGA package 320 has a different structure from the structures illustrated in the example embodiments of the present invention illustrated in FIGS. 3 through 5. According to an example embodiment of the present invention shown in FIG. 6, protrusions 340 may be formed at edges and portions adjacent to the edges of a first plane of the BGA package 320. The first plane of the BGA package 320 refers to the side where the input/output bonding pads 322 are positioned to be attached to the solder balls 330.

A plurality of the protrusions 340 may be arranged spaced apart from one another at intervals and may have a protruding length which is the same as or slightly less than the size (diameter) of the solder balls 330. The plurality of protrusions 340 may be arranged at regular or the same intervals from each other.

According to an example embodiment of the present invention, the protrusions 340 may be made of an elastic material, for example, tape, a polyimide or plastic material, or the same material as the supporting substrate of the BGA package 320. The protrusions 340 may include a single patterned interconnection layer, a number of patterned interconnection layers, or electronic devices electrically connected with the semiconductor die of the BGA package 320. If the electronic devices are included inside the protrusions 340, the electronic devices may be decoupling capacitors and/or resistors electrically connected with the semiconductor die.

As described above, in a printed circuit board of the integrated circuit modules according to example embodiments of the present invention, the space for mounting the electronic devices including the decoupling devices may not be required, or the space may be reduced as compared with conventional devices. Further, according to example embodiments of the present invention, the circuit pattern routing for the electronic devices may not be required. Further, because the circuit pattern routing may be possible on the printed circuit board in contact with the electronic devices, more efficient circuit pattern routing may be possible as compared to conventional devices.

In a semiconductor chip package according to an example embodiment of the present invention, the electronic devices instead of any supporting units may be disposed at the edges or portions adjacent to the edges of the semiconductor chip package, thereby reducing and/or preventing the occurrence of package cracks and/or solder joint cracks. Further, if the electronic devices are the decoupling devices, the decoupling devices may operate with increased efficiency because the decoupling devices may be disposed at a position adjacent to the semiconductor die.

The invention has been described herein using example embodiments of the present invention. However, it is to be understood that the scope of the invention is not limited to the disclosed example embodiments. On the contrary, the scope of the invention is intended to include various modifications and alternative arrangements within the capabilities of persons skilled in the art using presently known or future technologies and equivalents. The scope of the claims, therefore, should be accorded the broadest interpretation so as to encompass all such modifications and similar arrangements.

What is claimed is:

1. A semiconductor chip package comprising:
a supporting substrate;
a plurality of input/output bonding pads arranged on a first plane of the supporting substrate; and
a plurality of device bonding pads arranged on at least one of edges of the first plane and portions of the first plane adjacent to the edges.

2. The semiconductor chip package according to claim 1, further comprising:
a semiconductor die including a plurality of input/output pads,
wherein each of the plurality of input/output bonding pads are electrically connected to corresponding input/output pads of the semiconductor die.

3. The semiconductor chip package according to claim 1, wherein the semiconductor chip package has a ball grid array package structure.

4. The semiconductor chip package according to claim 1, wherein a plurality of solder balls having substantially a same size and ball pitch are attached to the input/output bonding pads.

5. The semiconductor chip package according to claim 1, wherein electronic devices including at least one of active devices and passive devices are attached to the device bonding pads.

6. The semiconductor chip package according to claim 5, wherein the electronic devices are at least one of smaller in size and same in size as the solder balls.

7. The semiconductor chip package according to claim 5, wherein the electronic devices are decoupling devices including at least one of capacitors and resistors.

8. The semiconductor chip package according to claim 2, wherein the device bonding pads are electrically connected with the input/output pads of the semiconductor die.

9. An integrated circuit module comprising:
a semiconductor chip package according to claim 4;
a plurality of electronic devices electrically connected with the device bonding pads; and
a printed circuit board electrically connected with the semiconductor chip package through the plurality of solder balls, but not electrically connected with the electronic devices.

10. The integrated circuit module according to claim 9, wherein the printed circuit board includes circuit pattern routing for mounting at least one second semiconductor chip package.

11. The integrated circuit module according to claim 10, wherein the at least one second semiconductor chip package has a ball grid array package structure.

12. The integrated circuit module according to claim 9, wherein the plurality of electronic devices includes at least one of active devices and passive devices.

13. The integrated circuit module according to claim 9, wherein each of the plurality of electronic devices are smaller in size or same in size as the plurality of solder balls.

14. The integrated circuit module according to claim 9, wherein the plurality of electronic devices are decoupling devices including at least one of capacitors and resistors.

15. An integrated circuit module comprising:
a semiconductor chip package according to claim 1; and
a semiconductor die including a plurality of input/output pads,
wherein the plurality of device bonding pads are electrically connected with the plurality of input/output pads of the semiconductor die.

16. An integrated circuit module comprising:
a semiconductor chip package according to claim 1;
a printed circuit board; and
an interposer providing an electrical connection between the semiconductor chip package and the printed circuit board.

17. The integrated circuit module according to claim 16, further comprising:
a plurality of first solder balls connected between the plurality of input/output pads of the supporting substrate and the interposer;
a plurality of second solder balls connected between the interposer and the printed circuit board; and
a plurality of electronic devices connected to the plurality of device bonding pads,
wherein the plurality of first solder balls are smaller in size than the plurality of electronic devices.

18. A semiconductor chip package comprising:
a supporting substrate;
a plurality of input/output bonding pads arranged on a first plane of the supporting substrate;
a semiconductor die including input/output pads, the input/output pads of the semiconductor die being connected to the input/output bonding pads; and
a plurality of protrusions having a length and being arranged on at least one of edges of the first plane and portions adjacent to the edges.

19. The semiconductor chip package according to claim 18, wherein the semiconductor chip package has a ball grid array package structure and includes solder balls having a same size and same ball pitch that are attached to the input/output bonding pads.

20. The semiconductor chip package according to claim 19, wherein the protrusions are at least one of smaller in size and same in size as the solder balls in size.

21. The semiconductor chip package according to claim 18, wherein the protrusions include at least one of decoupling capacitors and resistors.
